(19) United States
(12) Patent Application Publication
(10) Pub. No.: US 2024/0395690 A1
(43) Pub. Date: Nov. 28, 2024

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventor: Kenta NAKAHARA, Tokyo (JP)

(73) Assignee: Mitsubishi Electric Corporation, Tokyo (JP)

(21) Appl. No.: 18/695,493

(22) PCT Filed: Jan. 19, 2022
(86) PCT No.: PCT/JP2022/001785

§ 371 Date: Mar. 26, 2024

(51) Int. Cl. H01L 23/498; H01L 21/48; H01L 21/56; H01L 23/00; H01L 23/047; H01L 23/522; H01L 25/16

(52) U.S. Cl. CPC H01L 23/49844; H01L 21/4825; H01L 21/565; H01L 23/047; H01L 23/5223; H01L 23/562; H01L 24/32; H01L 24/48; H01L 24/73; H01L 25/16; H01L 2224/32; H01L 2224/48155; H01L 2224/73265; H01L 2924/1305; H01L 2924/13055; H01L 2924/13091; H01L 2924/19041

(57) ABSTRACT

Provided is a semiconductor device that reduces stress generated in a capacitor due to temperature changes in the semiconductor device, thereby suppressing damage to the capacitor. The semiconductor device includes an insulating substrate, a semiconductor element, a capacitor, a first lead having a surface, and a second lead having a surface, in which the insulating substrate includes an insulating layer and a conductor pattern provided on the insulating layer, the semiconductor element is bonded onto the conductor pattern, the first lead is electrically connected to the semiconductor element, the surface of the first lead and the surface of the second lead face each other, the capacitor is positioned between the surface of the first lead and the surface of the second lead facing each other, and the capacitor is connected to the first lead and the second lead.

### TECHNICAL FIELD

The present disclosure relates to a semiconductor device and a method of manufacturing the semiconductor device.

### BACKGROUND ART

In patent document 1, a semiconductor device equipped with a capacitor is disclosed.

### PRIOR ART DOCUMENTS

### Patent Document(s)

[Patent Document 1] International Publication No. 2018/008424

### SUMMARY

### Problem to be Solved by the Invention

In a semiconductor device equipped with a capacitor, stress is generated in the capacitor due to temperature changes in the semiconductor device, and damages the capacitor in some cases. Adequate consideration has not been given to such problems with conventional semiconductor devices.

The present disclosure has been made to solve the above problems, and an object thereof is to provide a semiconductor device that reduces stress generated in a capacitor due to temperature changes in the semiconductor device, thereby suppressing damage to the capacitor.

### Means to Solve the Problem

A semiconductor device of the present disclosure is a semiconductor device including an insulating substrate, a semiconductor element, a capacitor, a first lead having a surface, and a second lead having a surface, in which the insulating substrate includes an insulating layer and a conductor pattern provided on the insulating layer, the semiconductor element is bonded onto the conductor pattern, the first lead is electrically connected to the semiconductor element, the surface of the first lead and the surface of the second lead face each other, the capacitor is positioned between the surface of the first lead and the surface of the second lead facing each other, and the capacitor is connected to the first lead and the second lead.

### Effects of the Invention

According to the present disclosure, a semiconductor device that reduces stress generated in a capacitor due to temperature changes in the semiconductor device, thereby suppressing damage to the capacitor.

The objects, characteristics, aspects, and advantages of the technique disclosed in the present specification will become more apparent from the following detailed description and the accompanying drawings.

### BRIEF DESCRIPTION OF DRAWINGS

FIG. 1 A top view illustrating a semiconductor device of Embodiment 1.

FIG. 2 A side view illustrating the semiconductor device of Embodiment 1.

FIG. 3 A top view illustrating a semiconductor device of Embodiment 2.

FIG. 4 A side view illustrating the semiconductor device of Embodiment 2.

FIG. 5 A cross-sectional view of the semiconductor device of Embodiment 2 taken along line A-A in FIG. 3.

FIG. 6 A top view illustrating a semiconductor device according to Embodiment 3.

FIG. 7 A top view illustrating a semiconductor device according to Embodiment 4.

FIG. 8 A cross-sectional view of the semiconductor device of Embodiment 4 taken along line B-B in FIG. 7.

FIG. 9 A flowchart illustrating a method of manufacturing the semiconductor device of Embodiment 2.

### DESCRIPTION OF EMBODIMENT(S)

### A. Embodiment

### A-1. Configuration

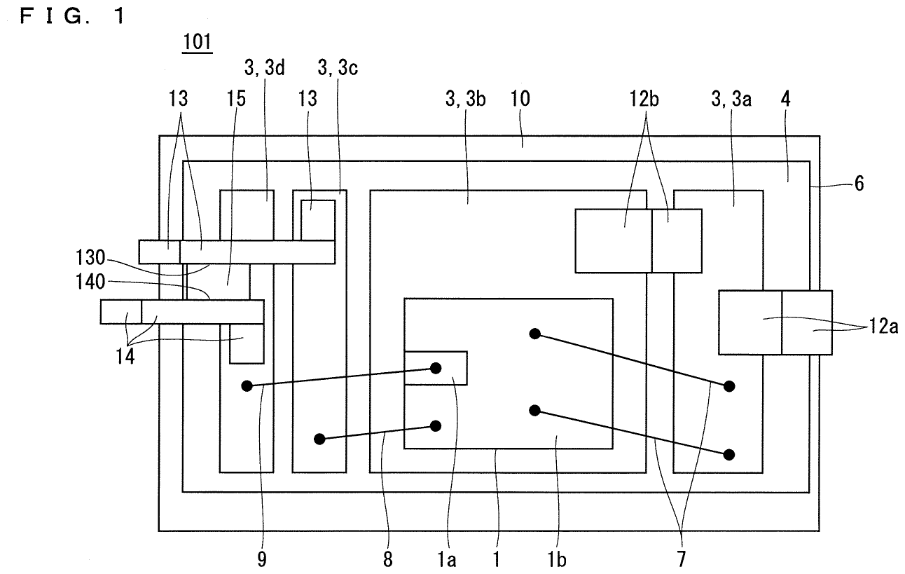

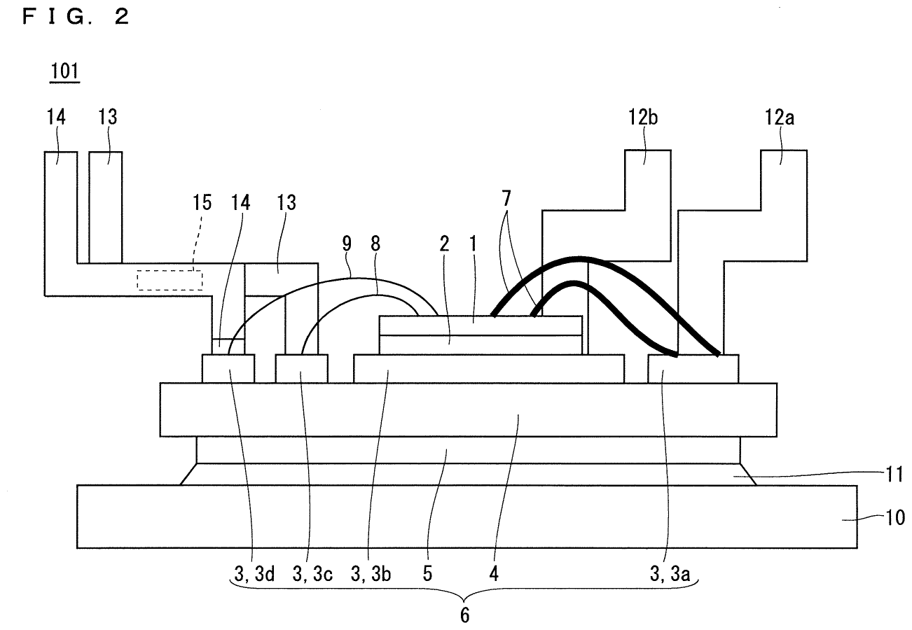

FIG. 1 is a top view of a semiconductor device 101 of Embodiment 1. FIG. 2 is a side view of the semiconductor device 101 of Embodiment 1.

The semiconductor device 101 includes a semiconductor element 1, solder 2, an insulating substrate 6, wires 7, a wire 8, a wire 9, a base plate 10, solder 11, a lead 12a, a lead 12b, a lead 13, a lead 14, and a capacitor 15.

The insulating substrate 6 includes an insulating layer 4, a conductor pattern 3 provided on one main surface of the insulating layer 4, and a conductor pattern 5 provided on the other main surface of the insulating layer 4.

The conductor pattern 5 is bonded to a base plate 10 via solder 11. That is, the insulating substrate 6 is bonded onto the base plate 10 via the solder 11.

The insulating substrate 6 may not need to include the conductor pattern 5. In that case, the insulating layer 4 is bonded to the base plate 10. The insulating layer 4 is directly bonded to the base plate 10, for example. The base plate 10 and the insulating substrate 6 may be integrated by directly bonding the insulating layer 4 and the base plate 10. The base plate 10 is attached to cooling fins, for example.

The semiconductor element 1 is a switching element. The semiconductor element 1 is, for example, a bipolar transistor, a Metal-Oxide-Semiconductor Field-Effect Transistor (MOSFET), an Insulated-Gate Bipolar Transistor (IGBT), or a Reverse-Conducting IGBT (RC-IGBT). Although FIG. 1 illustrates a case where the semiconductor device 101 includes one semiconductor element (that is, the semiconductor element 1), the semiconductor device 101 may include a plurality of semiconductor elements. For example, the semiconductor device 101 may include a plurality of switching elements. Also, for example, the semiconductor device 101 may include a switching element and a diode.

The conductor pattern 3 includes a conductor pattern 3a, a conductor pattern 3b, a conductor pattern 3c, and a conductor pattern 3d.

The semiconductor element 1 is bonded onto the conductor pattern 3b via the solder 2. In other words, the semiconductor element 1 is bonded onto the conductor pattern 3 via the solder 2.

The semiconductor element 1 includes a signal electrode 1a and a power electrode 1b.

The signal electrode 1a is an electrode for inputting a signal to the semiconductor element 1 to control the on/off of the semiconductor element 1, which is a switching element. The signal electrode 1a is a gate electrode when the semiconductor element 1 is a MOSFET or an IGBT. The signal electrode 1a is a base electrode when the semiconductor element 1 is a bipolar transistor.

The power electrode 1b is an emitter electrode when the semiconductor element 1 is an IGBT or a bipolar transistor. The power electrode 1b is a source electrode when the semiconductor element 1 is a MOSFET.

The power electrode 1b and the conductor pattern 3a are connected by the wires 7. The power electrode 1b and the conductor pattern 3c are connected by the wire 8. The signal electrode 1a and the conductor pattern 3d are connected by the wire 9.

The lead 12a is connected to the conductor pattern 3a. The lead 12b is connected to the conductor pattern 3b. The lead 13 is connected to the conductor pattern 3c. The lead 14 is connected to the conductor pattern 3d. The lead 12a, the lead 12b, the lead 13, and the lead 14 may each be bonded to the conductor patterns 3 via a bonding material such as solder (not illustrated), or may be directly bonded to the conductor patterns 3.

The lead 12a and the lead 12b are power leads.

The lead 13 and the lead 14 are signal leads.

The lead 13 is electrically connected to the power electrode 1b via the conductor pattern 3c and the wire 8. The potential of the power electrode 1b can be detected from outside the semiconductor device 101 via the lead 13.

The lead 14 is electrically connected to the signal electrode 1a via the conductor pattern 3d and the wire 9. A gate signal for controlling the semiconductor element 1 can be input to the semiconductor element 1 from outside the semiconductor device 101 via the lead 14.

The lead 13 has a surface 130. The lead 14 has a surface 140.

The lead 13 and the lead 14 are, for example, the leads having a flat plate shape, respectively. The surface 130 and the surface 140 are, for example, main surfaces of the lead 13 having a flat plate shape and the lead 14 having a flat plate shape, respectively, and having a certain width and extend.

The lead 13 and the lead 14 are arranged such that the surface 130 and the surface 140 face each other. The surface 130 and the surface 140 face each other in an in-plane direction of the insulating substrate 6.

The capacitor 15 is, for example, a ceramic capacitor. The use of a ceramic capacitor as capacitor 15 facilitates to improve the performance of semiconductor device 101.

The capacitor 15 is arranged between the surface 130 and the surface 140. The capacitor 15 is connected to the lead 13 and the lead 14.

The capacitor 15 is bonded to the surface 130 and the surface 140 using a bonding material (not illustrated) such as solder, for example.

One electrode (not illustrated) of the capacitor 15 is electrically connected to the lead 13, and the other electrode (not illustrated) of the capacitor 15 is electrically connected to the lead 14.

When the capacitor 15 is mounted on the conductor pattern 3, stress is generated in the capacitor 15 due to deformation of the insulating substrate 6 due to temperature changes, which may cause damage to the capacitor 15. When the capacitor 15 is mounted on the conductor pattern 3, the base plate 10 is greatly deformed due to temperature changes, and this deformation is transmitted to the capacitor 15 through the deformation of the insulating substrate 6, generating the large stress in the capacitor 15.

In the semiconductor device 101 of Embodiment 1, the capacitor 15 is mounted between the lead 13 and the lead 14; therefore, the influence of deformation of the insulating substrate 6 on the capacitor 15 is suppressed, reducing the stress generated in the capacitor 15. Consequently, damage to the capacitor 15 is suppressed and the reliability of the semiconductor device 101 is improved.

When the capacitor 15 is connected to the lead 13 and the lead 14 at a position away from the insulating substrate 6, the stress generated in the capacitor 15 due to the deformation of the insulating substrate 6 can be further reduced. The capacitor 15 may be separated from the insulating substrate 6 by a distance equal to or more than the distance between the surface 130 and the surface 140, for example. The capacitor 15 may be separated from the insulating substrate 6 by a distance twice the distance or more the distance between the surface 130 and the surface 140, for example.

By reducing the stress generated in the capacitor 15, the use of a capacitor with low mechanical strength is enabled as the capacitor 15.

The semiconductor element 1 is, for example, a semiconductor element using either a silicon semiconductor or a wide bandgap semiconductor. The wide bandgap semiconductor is a semiconductor with a larger bandgap than the silicon semiconductor. The wide bandgap semiconductor is, for example, a SiC semiconductor or a GaN semiconductor. When the semiconductor element 1 is a semiconductor using the wide gap semiconductor, the semiconductor device 101 can be operated at high speed. Further, when the semiconductor element 1 is a semiconductor using the wide gap semiconductor, the operation at a higher temperature is enabled than when the semiconductor element 1 is a semiconductor element using the silicon semiconductor. While a semiconductor element operates at a high temperature, the insulating substrate 6 is susceptible to deformation, in the semiconductor device 101 of Embodiment 1, damage to the capacitor 15 is suppressed with the influence of deformation of the insulating substrate 6 on the capacitor 15 suppressed.

In Embodiment 1, while the case has been described as an example where two leads (that is, the lead 13 and the lead 14) connected to the capacitor 15 are electrically connected to the same semiconductor element (that is, the semiconductor element 1), one of the two leads to which the capacitor 15 is connected may be electrically connected to the semiconductor element 1 and the other lead may not be electrically connected to the semiconductor element 1 and be led out of the semiconductor device 101, for example. Also, for example, the two leads to which the capacitor 15 is connected may be electrically connected to different semiconductor elements, respectively. Further, for example, the capacitor 15 may be connected to a power lead.

In the semiconductor device 101, the semiconductor element 1 and the capacitor 15 may be sealed with a sealing material, and the semiconductor device 101 may include a case in which the semiconductor element 1 is housed.

### B. Embodiment 2

### B-1. Configuration

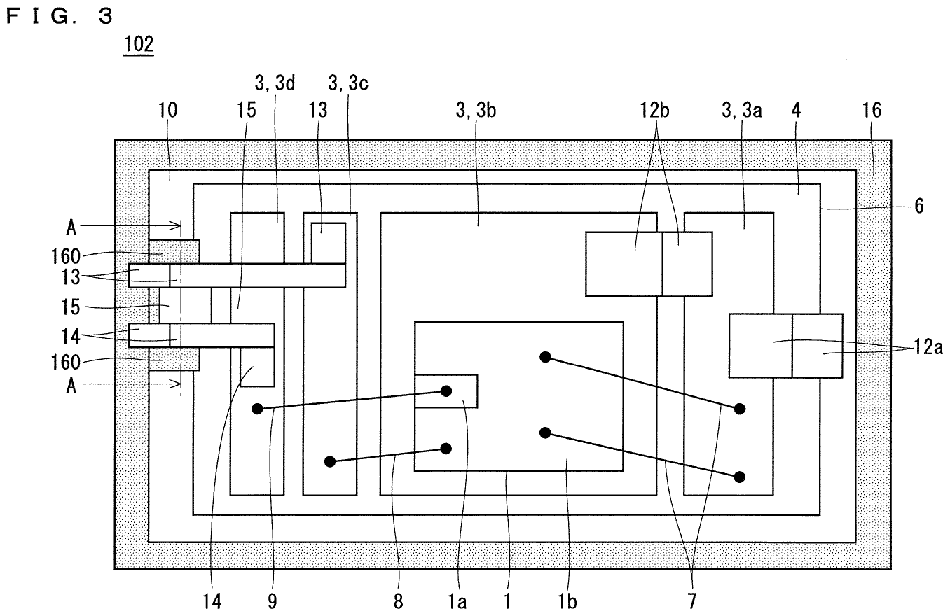

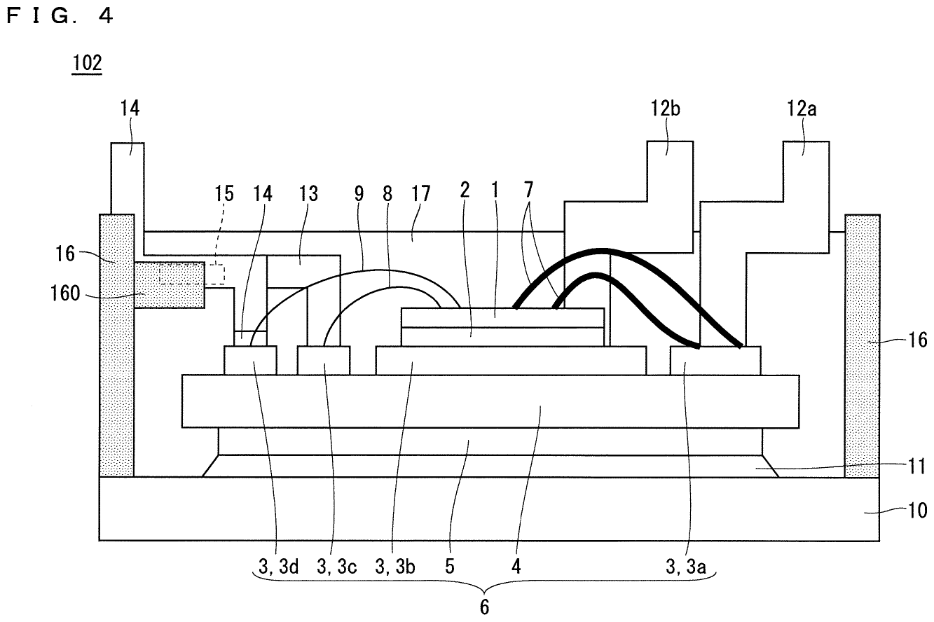

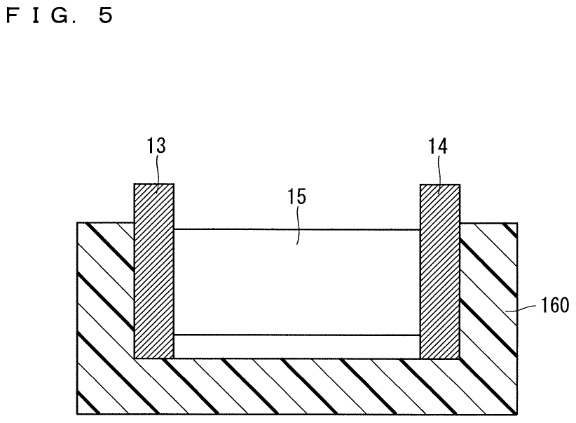

FIG. 3 is a top view of a semiconductor device 102 of Embodiment 2. FIG. 4 is a side view of the semiconductor device 102 of Embodiment 2. FIG. 5 is a cross-sectional view taken along line A-A in FIG. 3.

Differences from the semiconductor device 101 of Embodiment 1 are in that the semiconductor device 102 includes a case 16 and the positions of the lead 13 and the lead 14 are defined by the case 16. Also, the semiconductor device 102 differs from the semiconductor device 101 of Embodiment 1 in that the semiconductor element 1 and the capacitor 15 are sealed with a sealing material 17. The semiconductor device 102 of Embodiment 2 is similar to the semiconductor device 101 of Embodiment 1 in other respects.

In FIG. 3, the sealing material 17 is omitted for visibility. In FIG. 4, only a portion of the case 16 is illustrated for visibility, and the sealing material 17 is illustrated so as not to hide other elements.

The positions of the lead 13 and the lead 14 are defined by the case 16 so that the capacitor 15 can be mounted between the lead 13 and the lead 14. With this configuration, changes in the distance between the lead 13 and the lead 14 can be suppressed to facilitate mounting the capacitor 15 between the lead 13 and the lead 14 during manufacturing. Further, the efficiency of work such as checking the position where the capacitor 15 is mounted is improved. This improves productivity and yield thereof. Further, the quality of the semiconductor device 102 is improved because the positions of the lead 13 and the lead 14 are less likely to shift.

The lead 13 and the lead 14 are, for example, insert molded in the case 16, so that the positions of the lead 13 and the lead 14 are defined by the case 16.

A convex portion 160 that protrudes toward the inside of the case 16 is provided on the inner peripheral surface of the case 16. The lead 13 faces the convex portion 160 on the side opposite to the surface 130, and the lead 14 faces the convex portion 160 on the side opposite to the surface 140. The convex portion 160 defines the positions of the lead 13 and the lead 14.

While, FIGS. 3 to 5 illustrate a case in which one convex portion is provided on the inner peripheral surface of the case 16, a plurality of convex portions may be provided on the inner peripheral surface of the case 16, a convex portion the lead 13 faces on the side opposite to the surface 130 may be different from a convex portion the lead 14 faces on the side opposite to the surface 140.

Either the positions of the lead 13 and the lead 14 defined by insert molding the lead 13 and the lead 14 into the case 16, or the positions of the lead 13 and the lead 14 defined by the convex portion 160 may be adoptable.

Also in Embodiment 2, the capacitor 15 is mounted between the lead 13 and the lead 14, so that the stress generated in the capacitor 15 due to temperature changes in the semiconductor device 102 is reduced, suppressing the damage to the capacitor 15 and improving the reliability of the semiconductor device 102.

### B-2. Method of Manufacturing

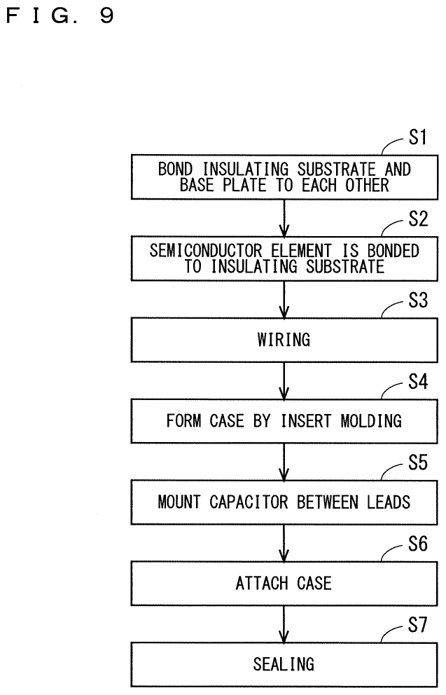

FIG. 9 is a flowchart illustrating an example of a method of manufacturing the semiconductor device of Embodiment 2.

First, the insulating substrate 6 and the base plate 10 are bonded (Step S1). Next, the semiconductor element 1 is bonded to the insulating substrate 6 (Step S2). Next, wiring is performed using the wires 7, the wire 8, and the wire 9 (Step S3).

Next, the lead 13 and the lead 14 are insert molded into the case 16 so that the surface 130 and the surface 140 face each other (Step S4). At this point, the lead 13 and the lead 14 are arranged at such positions that the capacitor 15 can be mounted between the lead 13 and the lead 14.

Next, the capacitor 15 is connected to the lead 13 and the lead 14, and the capacitor 15 is mounted between the lead 13 and the lead 14 (Step S5). Next, the case 16 is attached to the base plate 10 (Step S6). Next, the semiconductor element 1 and the capacitor 15 are sealed with the sealing material 17 (Step S6).

Through above Steps, the semiconductor device 102 is obtained. Step S4 and Step S5 may be performed before Steps S1, S2, and S3, or may be performed in parallel with Steps S1, S2, and S3. Further, Step S5 may be performed after Step S6 is performed.

### C. Embodiment 3

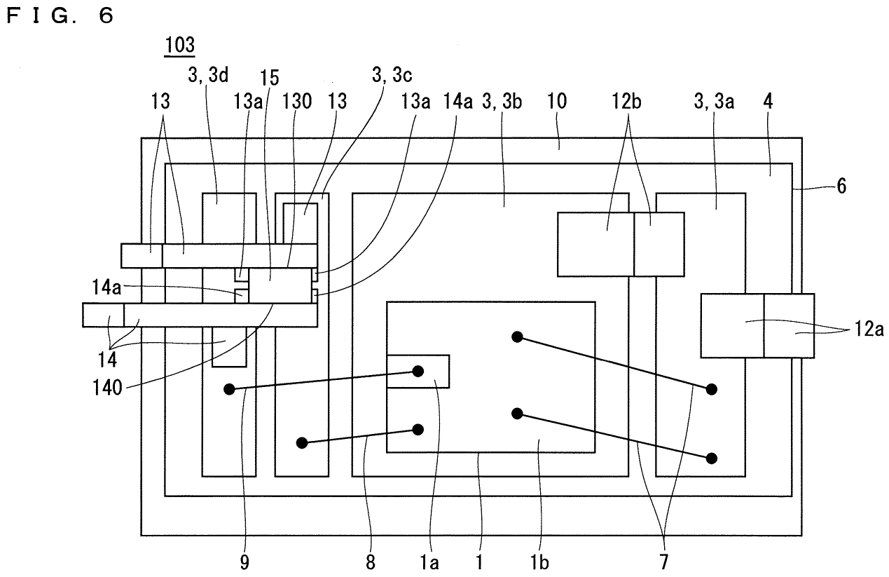

FIG. 6 is a top view of a semiconductor device 103 of Embodiment 3.

In the semiconductor device 103, the lead 13 includes a guide 13a protruding from the surface 130 in a direction perpendicular to the surface thereof. In the semiconductor device 103, the lead 14 includes a guide 14a protruding from the surface 140 in the direction perpendicular to the surface thereof. The semiconductor device 103 is similar to the semiconductor device 101 of Embodiment 1 except for these points.

The guide 13a faces the capacitor 15 in the in-plane direction of the surface 130. The guide 14a faces the capacitor 15 in the in-plane direction of the surface 140. The guide 13a and the guide 14a are positioned between the capacitor 15 and the insulating substrate 6.

In the semiconductor device 103, the lead 13 is provided with the guide 13a, and the lead 14 is provided with the guide 14a, thereby forming a pocket in which the capacitor 15 is mounted.

When manufacturing the semiconductor device 103, the position of the capacitor 15 in the in-plane direction of the surface 130 or the surface 140 is defined by the guide 13a and the guide 14a. With this, positioning of the capacitor 15 when mounting the capacitor 15 on the lead 13 and the lead 14 is facilitated, improving work efficiency. Further, the capacitor 15 does not require to be supported by a jig or the like, easing restrictions on the location where the capacitor 15 is mounted.

In Embodiment 3, while a case has been described in which the lead 13 is provided with the guide 13a and the lead 14 is provided with the guide 14a, either the lead 13 provided with the guide 13a or the lead 14 provided with the guide 14a may also be adopted.

Also in Embodiment 3, the capacitor 15 is mounted between the lead 13 and the lead 14, so that the stress generated in the capacitor 15 due to temperature changes in the semiconductor device is reduced, suppressing the damage to the capacitor 15 and improving the reliability of the semiconductor device 103.

In the semiconductor device 103, the semiconductor element 1 and the capacitor 15 may be sealed with a sealing material, and the semiconductor device 103 may include a case in which the semiconductor element 1 is housed. Similarly to the semiconductor device 102 of Embodiment 2, the semiconductor device 103 may include the case 16 that defines the positions of the lead 13 and the lead 14.

### D. Embodiment 4

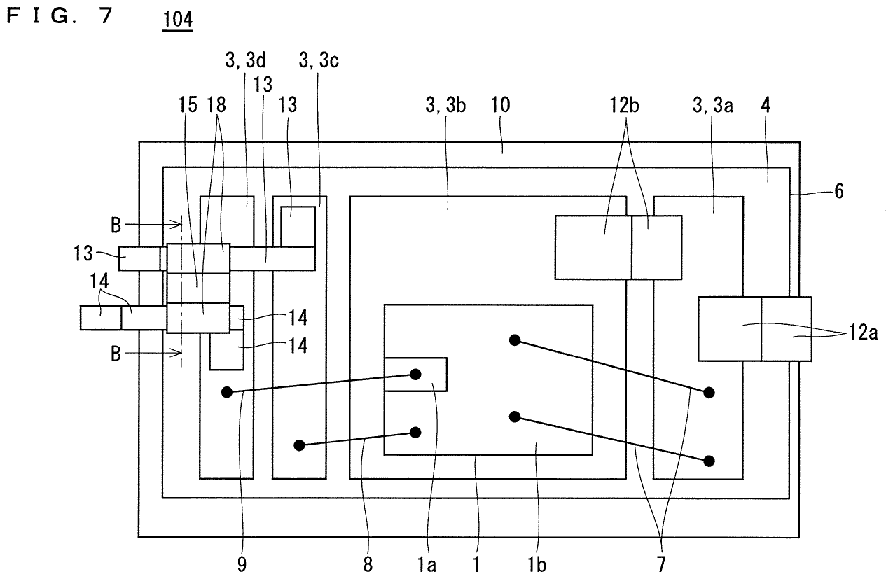

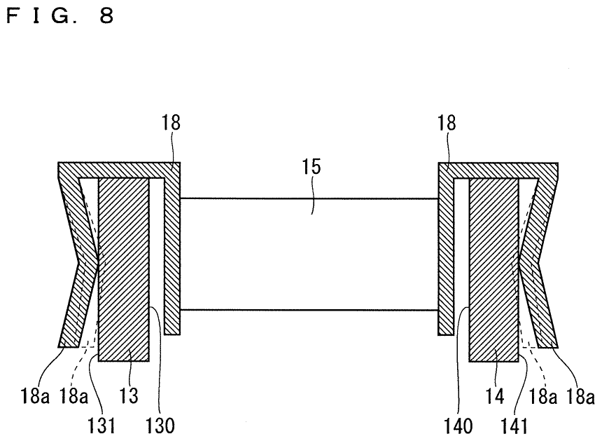

FIG. 7 is a top view of a semiconductor device 104 of Embodiment 4. FIG. 8 is a cross-sectional view of the semiconductor device 104 taken along line B-B in FIG. 7.

The difference from the semiconductor device 101 of Embodiment 1 is in that, in the semiconductor device 104, the capacitor 15 is connected to the lead 13 and the lead 14 via metal terminals 18. In other respects, the semiconductor device 104 is similar to the semiconductor device 101 of Embodiment 1.

Two metal terminals 18 are attached to the capacitor 15. The two metal terminals 18 are attached to the capacitor 15 via a bonding material (not illustrated) such as solder, for example.

Each of the two metal terminals 18 includes a holding portion 18a. For example, as illustrated in FIG. 8, the holding portion 18a has a convex shape toward the capacitor 15 side.

The holding portion 18a of one metal terminal 18 is in contact with a surface 131 of the lead 13 opposite to the surface 130, and the holding portion 18a of the other metal terminal 18 is in contact with a surface 141 of the lead 14 opposite to the surface 140. Accordingly, the two metal terminals 18 each interposes the lead 13 and the lead 14 therein, and the capacitor 15 is electrically connected to the lead 13 and the lead 14. The capacitor 15 and the lead 13 and the capacitor 15 and the lead 14 are electrically connected via metal terminals 18, respectively. The metal terminals 18 may or may not be in contact with the surface 130 and the surface 140.

When manufacturing the semiconductor device 104, the metal terminals 18 are attached to the capacitor 15, and then, the capacitor 15 is mounted between the lead 13 and the lead 14 so that the metal terminals 18 interpose the lead 13 and the lead 14, thereby, establishing electrical connection between the capacitor 15 and the lead 13 and the lead 14.

The distance between the holding portions 18a of the two metal terminals 18 attached to the capacitor 15 before attaching the capacitor 15 to the lead 13 and the lead 14, is shorter than the distance between the surface 131 of the lead 13 and the surface 141 of the lead 14 as illustrated by the broken lines in FIG. 8, for example. When the capacitor 15 is attached to the lead 13 and the lead 14, the electrical connection between the capacitor 15 and the lead 13 and the lead 14 is established more securely by the two holding portions 18a interposing the lead 13 and the lead 14 through elastic force.

The metal terminals 18, the lead 13, and the lead 14 may be bonded via a bonding material such as solder.

Also in Embodiment 4, the capacitor 15 is mounted between the lead 13 and the lead 14, so that the stress generated in the capacitor 15 is reduced, suppressing the damage to the capacitor 15 and improving the reliability of the semiconductor device 104.

In the semiconductor device 104, the semiconductor element 1 and the capacitor 15 may be sealed with a sealing material, and the semiconductor device 104 may include a case in which the semiconductor element 1 is housed. Similarly to the semiconductor device 102 of Embodiment 2, the semiconductor device 104 may include the case 16 that defines the positions of the lead 13 and the lead 14.

Also in the semiconductor device 104 of Embodiment 4, the lead 13 may be provided with the guide 13a, and the lead 14 may be provided with the guide 14a.

It should be noted that Embodiments can be arbitrarily combined and can be appropriately modified or omitted.

### EXPLANATION OF REFERENCE SIGNS

1 semiconductor element, la signal electrode, 1b power electrode, 2 solder, 3, 3a, 3b, 3c, 3d conductor pattern, 4 insulating layer, 5 conductor pattern, 6 insulating substrate, 7, 8, 9 wire, 10 base plate, 12a, 12b, 13, 14 lead, 13a, 14a guide, 15 capacitor, 16 case, 17 sealing material, 18 metal terminal, 18a holding portion, 101, 102, 103, 104 semiconductor device, 130, 131, 140, 141 surface, 160 convex portion.

1. A semiconductor device comprising:
an insulating substrate;
a semiconductor element;
a capacitor;
a first lead having a surface; and
a second lead having a surface, wherein
the insulating substrate includes an insulating layer and a conductor pattern provided on the insulating layer,
the semiconductor element is bonded onto the conductor pattern,
the first lead is electrically connected to the semiconductor element,
the surface of the first lead and the surface of the second lead face each other,
the capacitor is positioned between the surface of the first lead and the surface of the second lead facing each other, and
the capacitor is connected to the first lead and the second lead.

2. The semiconductor device according to claim 1, wherein
the surface of the first lead and the surface of the second lead face each other in an in-plane direction of the insulating substrate.

3. The semiconductor device according to claim 1, wherein
the second lead is electrically connected to the semiconductor element.

4. The semiconductor device according to claim 3, wherein
the semiconductor element is a switching element,
the semiconductor element includes a power electrode and a signal electrode,
the signal electrode is an electrode for a signal to control on/off of the semiconductor element,
the first lead is electrically connected to the power electrode, and
the second lead is electrically connected to the signal electrode.

5. The semiconductor device according to claim 1, wherein
either or both of that a guide is formed on the first lead, protruding from the surface of the first lead in a direction perpendicular to the surface, and facing the capacitor in the in-plane direction of the surface of the first lead, and that a guide is formed on the second lead, protruding from the surface of the second lead in the direction perpendicular to the surface, and facing the capacitor in the in-plane direction of the surface of the second lead.

6. The semiconductor device according to claim 1, wherein
a first metal terminal and a second metal terminal are attached to the capacitor, and
the first metal terminal is in contact with a side opposite to the surface of the first lead, and the second metal terminal is in contact with a side opposite to the surface of the second lead, thereby, interposing the first lead and the second lead by the first metal terminal and the second metal terminal.

7. The semiconductor device according to claim 1, further comprising
a base plate, wherein
the insulating substrate is bonded onto the base plate.

8. The semiconductor device according to claim 1, wherein
the semiconductor element is a semiconductor element including a SiC semiconductor.

9. The semiconductor device according to claim 1, further comprising
a case that houses the semiconductor element inside thereof, and
the first lead and the second lead are insert molded in the case.

10. The semiconductor device according to claim 1, further comprising
a case that houses the semiconductor element inside thereof,
at least one convex portion protruding toward the inside of the case is provided on the inner peripheral surface of the case,
the first lead faces one of the at least one convex portion on a side opposite to the surface of the first lead, and
the second lead faces one of the at least one convex portion on a side opposite to the surface of the second lead.

11. The semiconductor device according to claim 10, wherein
the first lead and the second lead are insert molded in the case.

12. A method of manufacturing the semiconductor device according to claim 1, wherein
the semiconductor device further comprises a case housing the semiconductor element inside thereof, comprising:
insert molding the first lead and the second lead in the case so that the surface of the first lead and the surface of the second lead face each other; and
after the insert molding, connecting the capacitor to the first lead and the second lead.

13. A method of manufacturing the semiconductor device according to claim 9, comprising:
insert molding the first lead and the second lead in the case so that the surface of the first lead and the surface of the second lead face each other; and
after the insert molding, connecting the capacitor to the first lead and the second lead.
